(19) United States
(12) Patent Application Publication
(10) Pub. No.: US 2025/0236816 A1
(43) Pub. Date: Jul. 24, 2025

(54) SURFACE TREATMENT COMPOSITION, METHOD FOR MANUFACTURING SURFACE TREATMENT COMPOSITION, SURFACE TREATMENT METHOD, AND METHOD FOR MANUFACTURING SEMICONDUCTOR SUBSTRATE

(71) Applicant: Fujimi Incorporated, Kiyosu-shi (JP)

(72) Inventor: Tsutomu Yoshino, Kiyosu-shi (JP)

(73) Assignee: Fujimi Incorporated, Kiyosu-shi (JP)

(21) Appl. No.: 19/176,925

(22) Filed: Apr. 11, 2025

Related U.S. Application Data
(62) Division of application No. 17/704,494, filed on Mar. 25, 2022.

(30) Foreign Application Priority Data
Mar. 31, 2021 (JP) 2021-59791

(51) Int. Cl. C11D 3/37; C11D 1/14; C11D 1/72; C11D 1/83; C11D 3/20; H01L 21/02

(52) U.S. Cl. CPC C11D 3/3773; C11D 1/83; C11D 3/2079; H01L 21/02065; H01L 21/02074; C11D 1/146; C11D 1/72; C11D 2111/22

(57) ABSTRACT

There is provided a means capable of sufficiently removing organic residues present on the surface of an object to be polished after polishing containing silicon nitride or polysilicon. A surface treatment composition containing: a polymer having a constituent unit represented by Formula (1) in [Chem. 1] below; at least one of an anionic surfactant and a nonionic surfactant; and water, in which the surface treatment composition is used for treating the surface of an object to be polished after polishing,

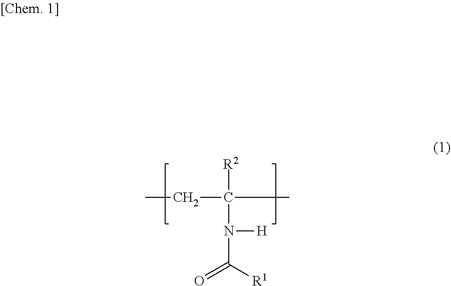

in which, in Formula (1) above, R¹ is a hydrocarbon group having the number of carbon atoms of 1 to 5, and R² is a hydrogen atom or a hydrocarbon group having the number of carbon atoms of 1 to 3.

### TECHNICAL FIELD

The present invention relates to a surface treatment composition, a method for manufacturing a surface treatment composition, a surface treatment method, and a method for manufacturing a semiconductor substrate.

### BACKGROUND ART

In recent years, with the multilayer wiring on the surface of a semiconductor substrate, a so-called chemical mechanical polishing (CMP) technology of polishing and flattening a semiconductor substrate has been utilized in manufacturing a semiconductor device. The CMP is a method for flattening the surface of objects to be polished (polishing targets), such as a semiconductor substrate, using a polishing composition (slurry) containing abrasives of silica, alumina, ceria, and the like, anticorrosive agents, surfactants, and the like. The objects to be polished (polishing targets) include silicon, polysilicon, a silicon oxide film (silicon oxide), silicon nitride, or wiring and plugs containing metal and the like, for example.

A large amount of impurities (defects) remains on the surface of the semiconductor substrate after a CMP step. The impurities include organic substances, such as abrasives, metals, anticorrosive agents, and surfactants derived from the polishing composition used in the CMP, silicon-containing materials and metals generated by polishing silicon-containing materials, metal wiring and plugs, and the like which are the objects to be polished, organic substances, such as pad chips generated from various types of pads, and the like.

When the surface of the semiconductor substrate is contaminated by these impurities, there is a possibility that the electrical characteristics of a semiconductor are adversely affected, which reduces the reliability of a semiconductor device. Therefore, it is desirable to introduce a cleaning step after the CMP step to remove these impurities from the surface of the semiconductor substrate.

As a cleaning liquid (cleaning composition) to be used for such a cleaning step, one disclosed in PTL 1 is mentioned, for example. PTL 1 discloses a slurry composition for chemical mechanical polishing containing water, polishing abrasives, and one or more types of water-soluble polymers containing polyvinyl alcohol structural units.

### CITATION LIST

### Patent Literature

PTL 1: JP 2012-74678 A

### SUMMARY OF INVENTION

### Technical Problem

A further reduction in defects has been desired when cleaning objects to be polished after polishing.

Herein, the present inventors have studied the relationship between the type of the objects to be polished after polishing and the type of the defects. As a result, the present inventors have found that organic residues are likely to remain on the surface of the objects to be polished after polishing (for example, semiconductor substrate after polishing) containing silicon nitride or polysilicon, and such organic residues can cause destruction of semiconductor devices.

The present invention has been made in view of the above-described problems. It is an object of the present invention to provide a means capable of sufficiently removing organic residues present on the surface of the objects to be polished after polishing containing silicon nitride or polysilicon.

### Solution to Problem

In view of the above-described problems, the present inventors have proceeded with intensive studies. As a result, the present inventors have found that the organic residues present on the surface of the objects to be polished after polishing containing silicon nitride or polysilicon can be sufficiently removed by the use of a surface treatment composition containing: a polymer having a constituent unit represented by Formula (1) in [Chem. 1] below; at least one of an anionic surfactant and a nonionic surfactant; and water, and thus have accomplished the present invention.

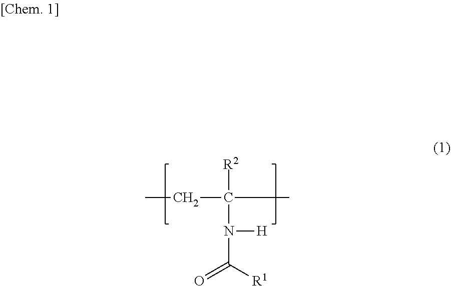

In Formula (1) above, R¹ is a hydrocarbon group having the number of carbon atoms of 1 to 5 and R² is a hydrogen atom or a hydrocarbon group having the number of carbon atoms of 1 to 3.

### Advantageous Effects of Invention

The present invention can provide the means capable of sufficiently removing the organic residues present on the surface of the objects to be polished after polishing containing silicon nitride or polysilicon.

### DESCRIPTION OF EMBODIMENTS

The present invention will now be described below. The present invention is not limited only to the following embodiment.

In this specification, the notation “(meth)acryl” in the specific names of compounds means “acryl” and “methacryl”, and the notation “(meth)acrylate” means “acrylate” and “methacrylate”.

### [Organic Residues]

In this specification, organic residues indicate components containing organic substances and organic salts, such as organic low molecular weight compounds and high molecular weight compounds, and the like among contaminants attached to the surface of objects to be polished after polishing.

The organic residues attached to objects to be cleaned include, for example, pad chips generated from a pad used in a polishing step described later or a rinse polishing step which may be optionally provided, components derived from additives contained in a polishing composition to be used in the polishing step or a rinse polishing composition to be used in the rinse polishing step, or the like.

The organic residues and the other contaminants are greatly different in color and shape, and therefore it can be visually determined whether the contaminants are the organic residues by SEM observation and may be determined by elemental analysis by an energy dispersive X-ray spectrometer (EDX) as necessary.

[Objects to be Polished after Polishing]

In this specification, the objects to be polished after polishing mean objects to be polished after being polished in the polishing step. The polishing step is not particularly limited, and is preferably a CMP step.

A surface treatment composition according to one aspect of the present invention is preferably used to reduce the organic residues remaining on the surface of the objects to be polished after polishing (hereinafter, also simply referred to as “objects to be cleaned”) containing silicon nitride (hereinafter, also simply referred to as “SiN”) or polysilicon (hereinafter, also simply referred to as “Poly-Si”).

The objects to be polished after polishing are preferably semiconductor substrates after polishing and more preferably semiconductor substrates after CMP. This is because particularly the organic residues can cause destruction of semiconductor devices, and therefore, when the objects to be polished after polishing are semiconductor substrates after polishing, a cleaning step of the semiconductor substrate is required to be a step capable of removing the organic residues as much as possible.

The objects to be polished after polishing containing silicon nitride or polysilicon include, but are not particularly limited to, objects to be polished after polishing containing simple substances of each of silicon nitride and polysilicon, objects to be polished after polishing in a state where silicon nitride or polysilicon and, in addition thereto, materials other than silicon nitride or polysilicon are exposed to the surface, and the like. Herein, the former includes a silicon nitride substrate or a polysilicon substrate, which is a semiconductor substrate. With respect to the latter, the materials other than silicon nitride or polysilicon include, but are not particularly limited to, tungsten and the like. Specific examples of such objects to be polished after polishing include semiconductor substrates after polishing having a structure in which a silicon nitride film or a polysilicon film is formed on tungsten, semiconductor substrates after polishing having a structure in which a tungsten part, a silicon nitride film, and a polysilicon film are all exposed, and the like.

Herein, from the viewpoint of the effects exhibited by the present invention, the objects to be polished after polishing according to one aspect of the present invention preferably contain polysilicon.

### [Surface Treatment Composition]

One aspect of the present invention is a surface treatment composition containing a polymer having a constituent unit represented by Formula (1) in [Chem. 2] below and water and used to treat the surface of the objects to be polished after polishing.

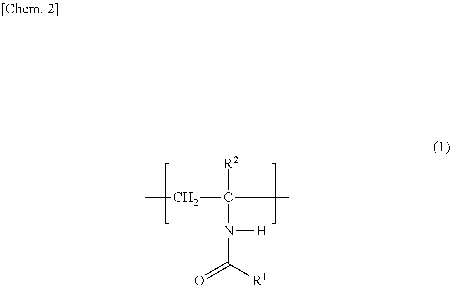

In Formula (1) above, R¹ is a hydrocarbon group having the number of carbon atoms of 1 to 5 and R² is a hydrogen atom or a hydrocarbon group having the number of carbon atoms of 1 to 3.

The surface treatment composition according to one aspect of the present invention is particularly preferably used as an organic residue reducing agent for selectively removing the organic residues in a surface treatment step.

The present inventors presume the mechanism by which the above-described problems are solved by the present invention as follows. The surface treatment composition has a function of removing the contaminants on the surface of the objects to be polished after polishing or facilitating the removal as a result of the interaction of each component contained in the surface treatment composition with the surface of the objects to be polished after polishing and the contaminants, i.e., as a result of a chemical interaction.

The polymer having the constituent unit represented by Formula (1) can change a hydrophobic surface to a hydrophilic surface by being physically adsorbed to the surface of a hydrophobic wafer. The organic residues attached onto the wafer are once lifted during the treatment, and then the polymer is adsorbed onto the wafer. As a result, the polymer forms a layer functioning as an organic residue reattachment prevention layer, and further enables easy removal of the organic residues from the wafer. For example, the polymer hydrophilizes the surface of polysilicon (Poly-Si) appearing on the surface of the wafer and removes the organic residues.

The above-described mechanism is based on the presumption, and the correctness thereof does not affect the technical scope of the present invention.

Hereinafter, each component contained in the surface treatment composition is described.

### [Polymer Having Constituent Unit Represented by Formula (1)]

As the hydrocarbon group having the number of carbon atoms of 1 to 5 represented by R¹ in Formula (1) above, alkyl groups, such as a methyl group, an ethyl group, and a propyl group; alkenyl groups, such as an ethenyl group and a propenyl group; alkynyl groups, such as an ethynyl group and a propynyl group; cycloalkyl groups, such as a cyclopentyl group; and the like can be mentioned. Among the above, the alkyl groups and the alkynyl groups are preferable, and the hydrocarbon group having the number of carbon atoms of 1 to 3 are also preferable. R¹ is more preferably the methyl group, the ethyl group, and the ethenyl group (vinyl group) and still more preferably the methyl group and the ethyl group.

As the hydrocarbon group having the number of carbon atoms of 1 to 3 represented by R² in Formula (1) above, those having the number of carbon atoms of 1 to 3 among those exemplified as the hydrocarbon group having the number of carbon atoms of 1 to 5 represented by R¹ can be mentioned. As R², a hydrogen atom and a methyl group are preferable.

Examples of unsaturated monomers giving the above-described constituent unit include N-vinylacetamide, N-vinylpropionamide, N-vinylbutylamide, and the like, and N-vinylacetamide and N-vinylpropionamide are preferable. One type of the unsaturated monomers can be used alone or two or more types thereof can be used in combination.

The weight average molecular weight (Mw) of the polymer is usually 30000 or more and 1000000 or less, preferably 50000 or more and 900000 or less, and more preferably 50000 or more and 100000 or less. By setting the weight average molecular weight (Mw) of the polymer in the ranges above, the organic residues on the surface of the objects to be polished after polishing can be more effectively reduced.

The lower limit value of the content (total content in the case of two or more types) of the polymer having the constituent unit represented by Formula (1) is not particularly limited and is preferably 0.02% by mass or more based on the total amount of the surface treatment composition. When the content is 0.02% by mass or more, the organic residues on the surface of the objects to be polished after polishing can be more effectively reduced.

From the same viewpoint, the lower limit value of the content of the polymer having the constituent unit represented by Formula (1) is more preferably 0.03% by mass or more and still more preferably 0.05% by mass or more based on the total amount of the surface treatment composition. On the other hand, the upper limit value of the content of the polymer having the constituent unit represented by Formula (1) is preferably 1% by mass or less based on the total amount of the surface treatment composition. When the content is 1% by mass or less, the removal of the polymer itself having the constituent unit represented by Formula (1) after the surface treatment is facilitated. From the same viewpoint, the upper limit value of the content of the polymer having the constituent unit represented by Formula (1) is more preferably 0.7% by mass or less and still more preferably 0.5% by mass or less based on the total amount of the surface treatment composition.

The content of the constituent unit in the polymer is preferably 30% by mol or more and 100% by mol or less, more preferably 50% by mol or more and 100% by mol or less, and still more preferably 70% by mol or more and 100% by mol or less. By setting the content of the constituent unit in the ranges above, the organic residues on the surface of the objects to be polished after polishing can be more effectively reduced.

[Water-Soluble Polymer Having Constituent Unit Derived from Glycerol]

The surface treatment composition according to one aspect of the present invention may contain a water-soluble polymer having a constituent unit derived from glycerol.

Preferable examples of the water-soluble polymer having a constituent unit derived from glycerol include at least one selected from the group consisting of polyglycerols (see Formula (2) below), alkyl (C10-14) esters of polyglycerols, polyglycerol alkyl (C10-14) ethers, ethylene oxide-modified polyglycerols, sulfonic acid-modified polyglycerols (see Formulae (3), (4) below, for example), and phosphonic acid-modified polyglycerols (see Formulae (5), (6) below, for example).

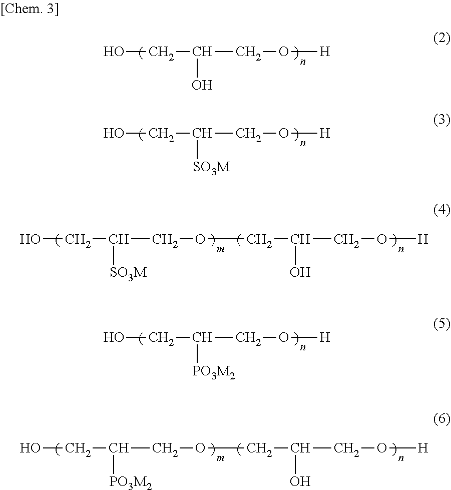

m and n in Formulae (2) to (6) above each independently represent the number of repeating units. Ms in Formulae (3) to (6) above each independently represent a hydrogen atom, Na, K, or NH₄+.

A plurality of Ms in Formulae (3) to (6) above may be the same or may be different from each other. For example, n pieces of Ms in Formula (3) above may be all Na or may be combinations of two or more types of a hydrogen atom, Na, K, and NH₄+. For example, m pieces of Ms in Formula (4) above may be all Na or may be combinations of two or more types of a hydrogen atom, Na, K, and NH₄+.

The water-soluble polymer having a constituent unit derived from glycerol can be used alone or in combination of two or more types thereof.

The content (concentration) (total content in the case of two or more types) of the water-soluble polymer having a constituent unit derived from glycerol is not particularly limited and is preferably 0.02% by mass or more based on the total amount of the surface treatment composition. When the content of the water-soluble polymer having a constituent unit derived from glycerol is 0.02% by mass or more, the effects of the present invention are enhanced.

From the same viewpoint, the content (concentration) of the water-soluble polymer having a constituent unit derived from glycerol is more preferably 0.03% by mass or more and still more preferably 0.05% by mass or more based on the total amount of the surface treatment composition. The content (concentration) of the water-soluble polymer having a constituent unit derived from glycerol is preferably 1% by mass or less based on the total amount of the surface treatment composition. When the content (concentration) of the water-soluble polymer having a constituent unit derived from glycerol is 1% by mass or less, the removal of the water-soluble polymer itself having a constituent unit derived from glycerol after the surface treatment is facilitated. From the same viewpoint, the content (concentration) of the water-soluble polymer having a constituent unit derived from glycerol is more preferably 0.7% by mass or less and still more preferably 0.5% by mass or less based on the total amount of the surface treatment composition.

The weight average molecular weight (Mw) of the water-soluble polymer having a constituent unit derived from glycerol is preferably 1000 or more. When the weight average molecular weight is 1000 or more, the contaminant removal effect is further enhanced. The reason therefor is presumed as follows: the covering properties when the water-soluble polymer having a constituent unit derived from glycerol covers the objects to be cleaned or the contaminants are further enhanced, so that an action of removing the contaminants from the surface of the objects to be cleaned or an action of suppressing the reattachment of the contaminants to the surface of the objects to be cleaned is further enhanced. From the same viewpoint, the weight average molecular weight is more preferably 3000 or more and still more preferably 8000 or more. The upper limit value of the weight average molecular weight of the water-soluble polymer having a constituent unit derived from glycerol is not particularly limited and is preferably 1000000 or less, more preferably 100000 or less, and still more preferably 50000 or less. The weight average molecular weight can be determined in terms of polyethylene glycol by gel permeation chromatography (GPC) using a GPC apparatus (model: Prominence+ELSD detector (ELSD-LTII) manufactured by Shimadzu Corporation) or the like, and specifically can be measured by a method described in Examples.

As the water-soluble polymer having a constituent unit derived from glycerol, commercially available products may be used or synthetic products may be used. Manufacturing methods when synthesizing the water-soluble polymer are not particularly limited, and known polymerization methods are usable.

### [Dispersion Medium]

The surface treatment composition according to one aspect of the present invention essentially contains water as a dispersion medium (solvent). The dispersion medium has a function of dispersing or dissolving each component. The dispersion medium more preferably contains only water. The dispersion medium may be a mixed solvent containing water and an organic solvent for dispersion or dissolution of each component. In this case, organic solvents to be used include acetone, acetonitrile, ethanol, methanol, isopropanol, glycerol, ethylene glycol, propylene glycol and the like, which are organic solvents miscible with water. These organic solvents may be used without being mixed with water, and may be mixed with water after each component is dispersed or dissolved. These organic solvents can be used alone or in combination of two or more types thereof.

The water is preferably water containing as little impurities as possible from the viewpoint of the contamination of the objects to be cleaned and the inhibition of the actions of the other components. For example, water having a total content of transition metal ions of 100 ppb or less is preferable. Herein, the purity of water can be increased by operations, such as the removal of impurity ions using an ion exchange resin, the removal of contaminants by a filter, and distillation, for example. Specifically, as the water, deionized water (ion-exchanged water), pure water, ultrapure water, distilled water, and the like are preferably used, for example.

### [Surfactant]

The surface treatment composition according to one aspect of the present invention contains at least one of an anionic surfactant and a nonionic surfactant (i.e., an anionic surfactant, a nonionic surfactant, or both of them). The anionic surfactant, the nonionic surfactant, or surfactants containing mixtures thereof contribute to the removal of the contaminants by the surface treatment composition. For example, the anionic surfactant and the nonionic surfactant individually disperse and remove particles and the organic residues attached onto silicon nitride (SiN). Hence, the surface treatment composition containing at least one of the anionic surfactant and the nonionic surfactant can sufficiently remove the contaminants (impurities containing the organic residues and the like) remaining on the surface of the objects to be polished after polishing in the surface treatment (cleaning or the like) of the objects to be polished after polishing.

The number of carbon atoms (C) in a hydrophobic part of the anionic surfactant is preferably 8 or more and 12 or less. When the number of carbon atoms in the hydrophobic part of the anionic surfactant is 8 or more and 12 or less (i.e., an alkyl chain in the hydrophobic part has a length corresponding to the number of carbon atoms of 8 to 12), the anionic surfactant is easily soluble in water, and thus high cleaning performance by the surface treatment composition can be held. When the number of carbon atoms in the hydrophobic part is 15 or more, the anionic surfactant becomes difficult to be dissolved in water, and thus the function as the surfactant tends to deteriorate. Ammonium dodecyl sulphate described in Examples below is an example of the anionic surfactant and has the number of carbon atoms in the hydrophobic part of 12.

Similarly, the number of carbon atoms (C) in the hydrophobic part of the nonionic surfactant is preferably 8 or more and 12 or less. When the number of carbon atoms in the hydrophobic part of the nonionic surfactant is 8 or more and 12 or less (i.e., an alkyl chain in the hydrophobic part has a length corresponding to the number of carbon atoms of 8 to 12), the nonionic surfactant is easily soluble in water, and thus high cleaning performance by the surface treatment composition can be held. When the number of carbon atoms in the hydrophobic part is 15 or more, the nonionic surfactant becomes difficult to be dissolved in water, and thus the function as the surfactant tends to deteriorate. Polyglycerol lauryl ether described in Examples below is an example of the nonionic surfactant and has the number of carbon atoms in the hydrophobic part of 12.

### [Anionic Surfactant]

Examples of the anionic surfactant include, for example, polyoxyethylene alkyl ether acetic acid, polyoxyethylene alkyl sulfate ester, alkyl sulfate ester, polyoxyethylene alkyl ether sulfuric acid, alkyl ether sulfuric acid, alkylbenzene sulfonic acid, alkyl phosphate ester, polyoxyethylene alkyl phosphate ester, polyoxyethylene sulfosuccinic acid, alkyl sulfosuccinic acid, alkylnaphthalene sulfonic acid, alkyldiphenyl ether disulfonic acid, and salts thereof, and the like. Among the above, alkyl sulfate ester, polyoxyethylene alkyl sulfate ester, polyoxyethylene alkyl ether sulfuric acid, alkyl ether sulfuric acid, alkylbenzene sulfonic acid, polyoxyethylene sulfosuccinic acid, and alkyl sulfosuccinic acid are preferable. Ammonium dodecyl sulphate described in Examples below is classified as alkyl sulfate ester. One type of the examples of the anionic surfactant described above may be used alone or two or more types thereof may be used in combination.

### [Nonionic Surfactant]

Examples of the nonionic surfactant include alkyl betaine, alkylamine oxide, polyoxyethylene alkyl ether, polyoxyalkylene alkyl ether, sorbitan fatty acid ester, glycerol fatty acid ester, polyoxyethylene fatty acid ester, polyoxyethylene alkylamine, alkyl alkanolamide, and the like. The other examples of the nonionic surfactant include polyglycerol-based surfactants. Examples of the polyglycerol-based surfactants include polyglycerol lauryl ester, polyglycerol lauryl ether, and the like. As the nonionic surfactant, polyoxyethylene alkyl ether, polyoxyalkylene alkyl ether, and the polyglycerol-based surfactants are preferable, and polyglycerol lauryl ester and polyglycerol lauryl ether are more preferable. One type of the examples of the nonionic surfactants mentioned above may be used alone or two or more types thereof may be used in combination.

[pH]

The surface treatment composition according to one aspect of the present invention has a pH value of 7 or more and preferably 7.5 or more. The surface treatment composition according to one aspect of the present invention has a pH value of 12 or less, preferably 11 or less, and more preferably 10 or less. When the surface treatment composition having a pH of 7 or more is used for the contaminants or the objects to be cleaned having the property of negatively charging the surface treatment composition, the surface of the objects to be cleaned or the surface of the contaminant can be negatively charged, and thus, due to the electrostatic repulsion, a high contaminant removal effect can be obtained.

The pH value of the surface treatment composition can be confirmed with a pH meter (product name: LAQUA (registered trademark) manufactured by HORIBA, Ltd.).

When adjusting the pH value, it is desirable not to add components other than the surface treatment composition according to one aspect of the present invention as much as possible because the components may induce contaminants. Therefore, it is preferable to prepare the surface treatment composition only using the water-soluble polymer having a constituent unit derived from glycerol, water, and at least one of the anionic surfactant and the nonionic surfactant. However, when it is difficult to obtain a desired pH using only the substances above, the surface treatment composition may be prepared using additives (for example, a pH adjuster described next) which can be optionally added within the range where the effects of the present invention are not impaired.

### [pH Adjuster]

The pH adjuster may be either acidic or alkaline and may be either an inorganic compound or an organic compound. In this specification, the anionic surfactant described above is treated as one different from acids as the pH adjuster described herein. The acids are added primarily for the purpose of adjusting the pH of the surface treatment composition.

Specific examples of the acids as the pH adjuster include inorganic acids and organic acids, such as carboxylic acids and organic sulfuric acids. Specific examples of the inorganic acids include sulfuric acid, nitric acid, boric acid, carbonic acid, hypophosphorous acid, phosphorous acid, phosphoric acid, and the like. As the pH adjuster, the inorganic acids are preferably used, and among the inorganic acids, phosphoric acid-based inorganic acids are more preferable. The organic acids include carboxylic acids, organic sulfuric acids, and organic phosphonic acids. Specific examples of the carboxylic acids include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glycerol acid, oxalic acid, malonic acid, succinic acid, glutaric acid, adipic acid, pimelic acid, maleic acid, phthalic acid, malic acid, tartaric acid, citric acid, lactic acid, and the like. Specific examples of the organic sulfuric acids include methanesulfonic acid, ethanesulfonic acid, isethionic acid, and the like. Specific examples of the organic phosphonic acids include methanephosphonic acid, etidronic acid, phenylphosphonic acid, and the like.

One type of these acids may be used alone or two or more types thereof may be used in combination. As the organic acids, carboxylic acid-based or phosphonic acid-based organic acids are preferably used. These acids may be contained as the pH adjuster, may be contained as additives for improving the polishing removal rate, or may be contained as a combination thereof in the surface treatment composition.

Specific examples of bases as the pH adjuster include hydroxides of alkali metals or salts thereof, hydroxides of alkaline earth metals or salts thereof, quaternary ammonium hydroxides or salts thereof, ammonia, amines, and the like. Specific examples of alkali metals include potassium, sodium, and the like. Specific examples of alkaline earth metals include calcium, strontium, and the like. Specific examples of salts include carbonates, hydrogen carbonates, sulfates, acetates, and the like. Specific examples of quaternary ammonium include tetramethylammonium, tetraethylammonium, tetrabutylammonium, and the like.

Examples of quaternary ammonium hydroxide compounds include quaternary ammonium hydroxides or salts thereof. Specific examples thereof include tetramethylammonium hydroxide, tetraethylammonium hydroxide, tetrabutylammonium hydroxide, and the like. Specific examples of amines include methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, anhydrous piperazine, piperazine hexahydrate, 1-(2-aminoethyl)piperazine, N-methylpiperazine, guanidine, and the like.

One type of these bases may be used alone or two or more types thereof may be used in combination. Among these bases, ammonia, ammonium salts, alkali metal hydroxides, alkali metal salts, quaternary ammonium hydroxide compounds, and amines are preferable, and ammonia, potassium compounds, sodium hydroxide, quaternary ammonium hydroxide compounds, ammonium hydrogen carbonate, ammonium carbonate, sodium hydrogen carbonate, and sodium carbonate are more preferable. Further, the surface treatment composition more preferably contains the potassium compounds as the base from the viewpoint of preventing metal contamination. Examples of the potassium compounds include potassium hydroxide or potassium salts. Specific examples thereof include potassium hydroxide, potassium carbonate, potassium hydrogen carbonate, potassium sulfate, potassium acetate, potassium chloride, and the like.

### [Chelating Agent]

The surface treatment composition according to one aspect of the present invention may contain a chelating agent as necessary in any proportion within the range where the effects of the present invention are not impaired. For example, the chelating agent has at least one of a phosphonic acid group and a carboxylic acid group. More specifically, the chelating agent may have only a phosphonic acid group, may have only a carboxylic acid group, or may have both a phosphonic acid group and a carboxylic acid group.

The chelating agent acts to suppress the contamination of the objects to be polished after polishing by the metal impurities, which can be contained in the surface treatment composition, by forming and capturing complex ions with the metal impurities. Examples of the chelating agent having a phosphonic acid group (hereinafter, also referred to as “phosphonic acid-based chelating agent”) include 1-hydroxyethylidene-1,1-diphosphonic acid (HEDP), nitrilotris(methylene phosphonic acid) (ATMP), ethylenediamine tetra(methylene phosphonic acid) (EDTMP), sodium hexametaphosphate, or 2-phosphonobutane-1,2,4-tricarboxylic acid (PBTC). Examples of the chelating agent having a carboxylic acid group (hereinafter, also referred to as “carboxylic acid-based chelating agent”) include triethylenetetraminehexacetic acid (TTHA), ethylenediaminetetraacetic acid (EDTA), diethylenetriaminepentaacetic acid (DTPA), ethylenediamine-N,N′-disuccinic acid (EDDS), succinic acid, glutaric acid, citric acid, and mercaptosuccinic acid.

The phosphonic acid-based chelating agent and the carboxylic acid-based chelating agent are not limited to the substances mentioned above, and may be the following examples, for example.

Examples of the phosphonic acid-based chelating agent include 2-aminoethylphosphonic acid, 1-hydroxyethylidene-1,1-diphosphonic acid, aminotri(methylene phosphonic acid), ethylenediaminetetrakis(methylene phosphonic acid) (EDTPO), diethylenetriaminepenta(methylene phosphonic acid), ethane-1,1-diphosphonic acid, ethane-1,1,2-triphosphonic acid, ethane-1-hydroxy-1,1-diphosphonic acid, ethane-1-hydroxy-1,1,2-triphosphonic acid, ethane-1,2-dicarboxy-1,2-diphosphonic acid, methanehydroxyphosphonic acid, 2-phosphonobutane-1,2-dicarboxylic acid, 1-phosphonobutane-2,3,4-tricarboxylic acid, and α-methylphosphonosuccinic acid. Among the above, EDTPO, diethylenetriaminepenta(methylene phosphonic acid), and diethylenetriaminepentaacetic acid are preferably mentioned. Particularly preferable phosphonic acid-based chelating agents include EDTPO and diethylenetriaminepenta(methylene phosphonic acid). Examples of the carboxylic acid-based chelating agent include ethylenediaminetetraacetic acid, sodium ethylenediaminetetraacetate, nitrilotriacetic acid, sodium nitrilotriacetate, ammonium nitrilotriacetate, hydroxyethylethylenediaminetriacetic acid, sodium hydroxyethylethylenediaminetriacetate, diethylenetriaminepentaacetic acid, sodium diethylenetriaminepentaacetate, triethylenetetraminehexaacetic acid, and sodium triethylenetetraminehexaacetate. One type of the chelating agents can be used alone or two or more types thereof can be used in combination.

### [Other Additives]

The surface treatment composition according to one aspect of the present invention may contain the other additive as necessary in any proportion within the range where the effects of the present invention are not impaired. However, components other than the essential components of the surface treatment composition according to one aspect of the present invention may induce contaminants, and therefore it is desirable not to add the components as much as possible. Hence, it is preferable that the addition amount of the components other than the essential components is as small as possible and it is more preferable that the components are not contained. The other additives include abrasives, alkali, antiseptic agents, dissolved gases, reducing agents, oxidants, alkanolamines, and the like, for example. In particular, in order to further improve the contaminant removal effect, it is preferable that the surface treatment composition is substantially free of abrasives. Herein, the description “substantially free of abrasives” means that the content of abrasives based on the entire surface treatment composition is 0.01% by mass or less.

For the number of the contaminants (organic residues), a value is adopted which is measured by a method described in Examples after the surface treatment is performed by a method described in Examples.

### [Method for Manufacturing Surface Treatment Composition]

A method for manufacturing the above-described surface treatment composition is not particularly limited. For example, the surface treatment composition can be manufactured by mixing the polymer having the constituent unit represented by Formula (1) above, water, and at least one of the anionic surfactant and the nonionic surfactant. More specifically, another aspect of the present invention also provides a method for manufacturing the above-described surface treatment composition including mixing the polymer having the constituent unit represented by Formula (1) above, water, and at least one of the anionic surfactant and the nonionic surfactant.

The type of the polymer having the constituent unit represented by Formula (1) above, the type of the anionic surfactant, the type of the nonionic surfactant, the addition amount, and the like are as described above. Further, in the method for manufacturing the surface treatment composition according to one aspect of the present invention, the water-soluble polymer (glycerol-based water-soluble polymer) having a constituent unit derived from glycerol, the pH adjuster, the chelating agent, the other additives, the dispersion medium other than water described above, and the like may be further mixed as necessary. The type, addition amount, and the like thereof are as described above.

The order of adding the above-described components and methods for adding the above-described components are not particularly limited. The above-described materials may be added at once or separately or stepwise or successively. Mixing methods are not particularly limited, and known methods are usable. Preferably, the method for manufacturing the surface treatment composition includes sequentially adding the water-soluble polymer having a constituent unit derived from glycerol, water, and at least one of the anionic surfactant and the nonionic surfactant, and the pH adjuster and the like added as necessary, and stirring them in water. In addition, the method for manufacturing the surface treatment composition may further include measuring and adjusting the pH of the surface treatment composition such that the pH is 7 or more and 12 or less.

### [Surface Treatment Method]

Another aspect of the present invention is a surface treatment method including surface treating the objects to be polished after polishing using the above-described surface treatment composition. In this specification, the surface treatment method refers to a method for reducing the contaminants on the surface of the objects to be polished after polishing, and is a method for performing cleaning in a broad sense.

The surface treatment method according to one aspect of the present invention enables sufficient removal of the contaminants remaining on the surface of the objects to be polished after polishing. More specifically, another aspect of the present invention provides a method for reducing the contaminants on the surface of the objects to be polished after polishing including surface treating the objects to be polished after polishing using the above-described surface treatment composition.

The surface treatment method according to one aspect of the present invention is performed by bringing the surface treatment composition according to the present invention into direct contact with the objects to be polished after polishing.

The surface treatment method mainly includes (I) a method by rinse polishing treatment and (II) a method by cleaning treatment. More specifically, the surface treatment according to one aspect of the present invention is preferably performed by rinse polishing or cleaning. The rinse polishing treatment and the cleaning treatment are carried out to remove the contaminants (particles, metal contamination, organic residues, pad chips, and the like) on the surface of the objects to be polished after polishing to obtain a clean surface. The (I) and (II) above are described below.

### (I) Rinse Polishing Treatment

The surface treatment composition according to the present invention is preferably used in the rinse polishing treatment. The rinse polishing treatment is performed on a polishing platen mounted with a polishing pad for the purpose of removing the contaminants on the surface of the objects to be polished after final polishing of the objects to be polished is performed. At this time, the rinse polishing treatment is performed by bringing the surface treatment composition according to the present invention into direct contact with the object to be polished after polishing. As a result, the contaminants on the surface of the object to be polished after polishing are removed by a frictional force (physical action) by the polishing pad and a chemical action by the surface treatment composition. Among the contaminants, particularly the particles or the organic residues are likely to be removed by the physical action. Therefore, in the rinse polishing treatment, the particles or the organic residues can be effectively removed utilizing the friction with the polishing pad on the polishing platen.

Specifically, the rinse polishing treatment can be performed by arranging the surface of the object to be polished after polishing after the polishing step on the polishing platen of a polishing apparatus, bringing the polishing pad and a semiconductor substrate after polishing into contact with each other, and then relatively sliding the object to be polished after polishing and the polishing pad while supplying the surface treatment composition (rinse polishing composition) to the contact portion.

The rinse polishing treatment can be performed using either a single-sided polishing apparatus or a double-sided polishing apparatus. The polishing apparatus preferably includes a rinse polishing composition discharge nozzle in addition to a polishing composition discharge nozzle. The operation conditions in the rinse polishing treatment of the polishing apparatus are not particularly limited and can be appropriately set by those skilled in the art.

### (II) Cleaning Treatment

The surface treatment composition according to the present invention is preferably used in the cleaning treatment. The cleaning treatment is performed for the purpose of removing the contaminants on the surface of the objects to be polished after final polishing of the objects to be polished is performed or after the above-described rinse polishing treatment of the objects to be polished is performed. The cleaning treatment and the above-described rinse polishing treatment are classified according to a place where the treatment is performed, and the cleaning treatment is surface treatment performed after removing the object to be polished after polishing from the polishing platen. Also in the cleaning treatment, the contaminants on the surface of the object to be polished after polishing can be removed by bringing the surface treatment composition according to the present invention into direct contact with the object.

Examples of a method for performing the cleaning treatment include (i) a method including, in a state of holding the object to be polished after polishing, bringing a cleaning brush into contact with one side or both sides of the object to be polished after polishing, and then rubbing the surface of the object to be cleaned with the cleaning brush while supplying the surface treatment composition to the contact part, (ii) a method including dipping the object to be polished after polishing in the surface treatment composition, and then performing ultrasonic treatment or stirring (dip type), and the like. In such methods, the contaminants on the surface of the object to be polished are removed by a frictional force by the cleaning brush or a mechanical force generated by the ultrasonic treatment or the stirring and a chemical action by the surface treatment composition.

In the method (i) above, a method for bringing the surface treatment composition (cleaning composition) into contact with the object to be polished after polishing is not particularly limited and a spin type including rotating the object to be polished after polishing at high speed while pouring the surface treatment composition from a nozzle onto the object to be polished after polishing, a spray type including spraying the surface treatment composition to the object to be polished after polishing for cleaning, and the like are mentioned.

From the viewpoint that more efficient decontamination can be performed in a short time, the spin type or the spray type is preferably adopted and the spin type is more preferably adopted as the cleaning treatment.

Apparatus for performing such cleaning treatment includes a batch-type cleaning apparatus for surface treating two or more of the objects to be polished after polishing stored in a cassette at once, a single-wafer cleaning apparatus for attaching one object to be polished after polishing to a holder and surface treating the same, and the like. From the viewpoint of shortening the cleaning time, a method using the single-wafer cleaning apparatus is preferable.

Further, the apparatus for performing the cleaning treatment includes a polishing apparatus including a cleaning facility for rubbing the object to be polished after polishing with a cleaning brush after removing the object from the polishing platen. By the use of such a polishing apparatus, the cleaning treatment of the object to be polished after polishing can be more efficiently performed.

As such a polishing apparatus, a common polishing apparatus is usable which has a holder holding the object to be polished after polishing, a motor capable of changing the number of rotations, a cleaning brush, and the like. As the polishing apparatus, either a single-sided polishing apparatus or a double-sided polishing apparatus may be used. When the rinse polishing step is performed after the CMP step, it is more efficient and preferable to perform the cleaning treatment using the same apparatus as the polishing apparatus used in the rinse polishing step.

The cleaning brush is not particularly limited, and a resin brush is preferably used. Materials of the resin brush are not particularly limited, and PVA (polyvinyl alcohol) is preferably used, for example. As the cleaning brush, a PVA sponge is particularly preferably used.

The cleaning conditions are also not particularly limited, and can be appropriately set according to the type of the object to be cleaned and the type and the amount of the organic residues to be removed. For example, it is preferable that the number of rotations of the cleaning brush is 10 rpm or more and 200 rpm or less, the number of rotations of the object to be cleaned is 10 rpm or more and 100 rpm or less, and the pressure (polishing pressure) applied to the object to be cleaned is 0.5 psi or more and 10 psi or less. A method for supplying the surface treatment composition to the cleaning brush is also not particularly limited, and a method for successively supplying the surface treatment composition with a pump or the like (one-way) is adopted, for example. The supply amount is not limited, and it is preferable that the cleaning brush and the surface of the object to be cleaned are constantly covered with the surface treatment composition, and the supply amount is preferably 10 mL/min or more and 5000 mL/min or less. The cleaning time is also not particularly limited, and is preferably 5 seconds or more and 180 seconds or less for a step using the surface treatment composition according to one aspect of the present invention. Within such a range, the contaminants can be more effectively removed.

The temperature of the surface treatment composition in the cleaning is not particularly limited and may be usually room temperature (25° C.), but may be increased to about 40° C. or more and 70° C. or less within the range where the performance is not impaired.

In the method (ii) above, the conditions of the cleaning method by dipping are not particularly limited, and known methods are usable.

Before, after, or both before and after the cleaning treatment according to the methods (i), (ii) above, cleaning with water may be performed.

The object to be polished after polishing (object to be cleaned) after cleaning is preferably dried by removing water droplets attached to the surface with a spin dryer or the like. The surface of the object to be cleaned may be dried by air blow drying.

### [Method for Manufacturing Semiconductor Substrate]

The surface treatment method according to one aspect of the present invention is suitably applicable when the object to be polished after polishing is a semiconductor substrate after polishing. More specifically, another aspect of the present invention also provides a method for manufacturing a semiconductor substrate in which the object to be polished after polishing is a semiconductor substrate after polishing and which includes surface treating the semiconductor substrate after polishing using the above-described surface treatment composition.

The details of the semiconductor substrate to which the manufacturing method is applied are as described in the description of the object to be polished after polishing to be surface treated by the above-described surface treatment composition.

The method for manufacturing a semiconductor substrate is not particularly limited insofar as it includes a step of surface treating the surface of the semiconductor substrate after polishing using the surface treatment composition according to one aspect of the present invention (surface treatment step). Such a manufacturing method includes a method having the polishing step for forming the semiconductor substrate after polishing and the cleaning step. As another example, a method is mentioned which has, in addition to the polishing step and the cleaning step, the rinse polishing step between the polishing step and the cleaning step. Hereinafter, each step is described.

### <Polishing Step>

The polishing step, which can be included in the method for manufacturing a semiconductor substrate, is a step of polishing a semiconductor substrate to form a semiconductor substrate after polishing.

The polishing step is not particularly limited insofar as it is a step of polishing a semiconductor substrate, and is preferably a chemical mechanical polishing (CMP) step. The polishing step may be a polishing step including a single step or a polishing step including a plurality of steps. The polishing step including a plurality of steps includes a step of performing a final polishing step after a stock polishing step (rough polishing step), a step of performing one or more times of a secondary polishing step after a primary polishing step, and then performing a final polishing step, and the like, for example. The surface treatment step using the surface treatment composition according to the present invention is preferably performed after the above-described final polishing step.

As the polishing composition, known polishing compositions can be used as appropriate according to the characteristics of the semiconductor substrate. The polishing composition is not particularly limited, and polishing compositions containing abrasives, acid salts, dispersion media, and acids and the like can be preferably used, for example. Specific examples of such polishing compositions include polishing compositions containing ceria, polyacrylic acid, water, and maleic acid and the like.

As the polishing apparatus, a common polishing apparatus having a polishing platen is usable, the polishing platen which is mounted with a holder holding the object to be polished, a motor capable of changing the number of rotations, and the like and to which a polishing pad (polishing cloth) can be attached. As the polishing apparatus, either a single-sided polishing apparatus or a double-sided polishing apparatus may be used.

As the polishing pad, common non-woven fabric, polyurethane, porous fluororesin, and the like can be used without particular limitation. The polishing pad is preferably grooved such that a polishing liquid is collected.

The polishing conditions are also not particularly limited. For example, the number of rotations of the polishing platen and the number of rotations of a head (carrier) are preferably 10 rpm or more and 100 rpm or less and the pressure (polishing pressure) applied to the object to be polished is preferably 0.5 psi or more and 10 psi or less. A method for supplying the polishing composition to the polishing pad is also not particularly limited, and a method for successively supplying the polishing composition with a pump or the like (one-way) is adopted, for example. The supply amount is not limited, and the surface of the polishing pad is preferably constantly covered with the polishing composition. The supply amount is preferably 10 mL/min or more and 5000 mL/min or less. The polishing time is not particularly limited, and is preferably 5 seconds or more and 180 seconds or less for a step using the polishing composition.

### <Surface Treatment Step>

The surface treatment step is a step of reducing the contaminants on the surface of the object to be polished after polishing using the surface treatment composition according to the present invention. In the method for manufacturing a semiconductor substrate, the cleaning step as the surface treatment step may be performed after the rinse polishing step or only the rinse polishing step or only the cleaning step may be performed.

### (Rinse Polishing Step)

The rinse polishing step may be provided between the polishing step and the cleaning step in the method for manufacturing a semiconductor substrate. The rinse polishing step is a step of reducing the contaminants on the surface of the object to be polished after polishing (semiconductor substrate after polishing) by the surface treatment method (rinse polishing treatment method) according to one aspect of the present invention.

With respect to the apparatus, such as the polishing apparatus and the polishing pad, and the polishing conditions, the same apparatus and conditions as those in the polishing step above can be applied, except that the surface treatment composition according to the present invention is supplied instead of supplying the polishing composition.

The details of the rinse polishing method used in the rinse polishing step are as described in the description relating to the rinse polishing treatment above.

### (Cleaning Step)

The cleaning step may be provided after the polishing step or after the rinse polishing step in the method for manufacturing a semiconductor substrate. The cleaning step is a step of reducing the contaminants on the surface of the object to be polished after polishing (semiconductor substrate after polishing) by the surface treatment method (cleaning method) according to one aspect of the present invention.

The details of the cleaning method used in the cleaning step are as described in the description relating to the cleaning method above.

### EXAMPLES

The present invention is described in more detail with reference to Examples and Comparative Examples below. However, the technical scope of the present invention is not limited to Examples below. Unless otherwise specified, “%” and “part(s)” mean “% by mass” and “part(s) by mass”, respectively. In Examples below, unless otherwise specified, the operation was performed under the conditions of room temperature (25° C.)/relative humidity of 40 to 50% RH.

For the weight average molecular weight of each polymer compound, a value of the weight average molecular weight (in terms of polyethylene glycol) measured by gel permeation chromatography (GPC) is used, and, more specifically, the weight average molecular weight was measured by the following apparatus and under the following conditions.
GPC apparatus: manufactured by Shimadzu Corporation
Model: Prominence+ELSD detector (ELSD-LTII)
Column: VP-ODS (manufactured by Shimadzu Corporation)
Mobile phase A: MeOH
   B: aqueous 1% acetic acid solution
Flow rate: 1 mL/min
Detector: ELSD, temp. 40° C., Gain 8, N2 GAS 350 kPa
Oven temperature: 40° C.
Injection amount: 40 μL

### <Preparation of Surface Treatment Composition>

### Example 1: Preparation of Surface Treatment Composition (A-1)

1.25 g/L of poly-N-vinylacetamide (weight average molecular weight (Mw): 50000; constituent unit represented by Formula (1): 100% by mol) and 1.00 g/L of ammonium dodecyl sulphate (weight average molecular weight (Mw): 288) as an anionic surfactant were individually mixed with water (deionized water), and then ammonium acetate as a pH adjuster was added in such an amount that the pH reached 8.7, thereby preparing a surface treatment composition (A-1). The pH of the surface treatment composition (A-1) (liquid temperature: 25° C.) was measured with a pH meter (product name: LAQUA (registered trademark) manufactured by HORIBA, Ltd.). In Table 1, PNVA indicates “poly-N-vinylacetamide”.

### Examples 2 to 10 and Comparative Examples 1 to 6: Preparation of Surface Treatment Compositions (A-2) to (A-10), and (a-1) to (a-6)

Surface treatment compositions were prepared by the same operation as in Example 1, except that each component of the type, the molecular weight, and the content shown in Table 1 was used and the pH of each of the surface treatment compositions was adjusted to the pH shown in Table 1. In Table 1, “-” indicates that the marked component was not used. In Table 1, PSS-PA indicates a “polystyrene sulfonic acid-acrylic acid copolymer”.

PSS-PA is an anionic polymer and not a surfactant. More specifically, PSS-PA does not function as a surfactant because the alkyl chain in the hydrophobic part is longer and the molecular weight of the hydrophobic part is larger as compared with those of the anionic surfactant.

In Table 1, ammonium dodecyl sulphate is classified as an anionic surfactant. Polyglycerol lauryl ether is classified as a nonionic surfactant. The total molecular weight of polyglycerol lauryl ether is larger than that of ammonium dodecyl sulphate, but the molecular weight of the hydrophobic part of polyglycerol lauryl ether is as small as that of ammonium dodecyl sulphate. Therefore, polyglycerol lauryl ether functions as a surfactant.

### Evaluation

<Preparation of Objects to be Polished after Polishing (Objects to be Surface Treated)>

A polished silicon nitride substrate and a polished polysilicon substrate after being polished by the following chemical mechanical polishing (CMP) step or a polished silicon nitride substrate and a polished polysilicon substrate after being further treated by the following rinse step as necessary were prepared as objects to be surface treated.

### [CMP Step]

The silicon nitride substrate and the polysilicon substrate which are semiconductor substrates were polished under the following conditions using 1% by mass of a polishing composition M (composition: ceria, primary particle diameter of 60 nm, secondary particle diameter of 100 nm), 0.18% by mass of aqueous 30% by mass concentration maleic acid solution, 0.25% by mass of polyacrylic acid (molecular weight: 6000), and water as a solvent. Herein, a 300 mm wafer was used as the silicon nitride substrate and the polysilicon substrate.

### (Polishing Apparatus and Polishing Conditions)

Polishing apparatus: FREX 300E manufactured by Ebara Corporation
Polishing pad: Soft pad H800 manufactured by Fujibo Co., Ltd.
Polishing pressure: 2.0 psi (1 psi=6894.76 Pa, which similarly applies in the following description)
Number of rotations of polishing platen: 90 rpm
Number of rotations of head: 90 rpm
Supply of polishing composition: One-way
Polishing composition supply amount: 200 mL/min
Polishing time: 60 seconds

### [Rinse Polishing Treatment Step]

With respect to the polished silicon nitride substrate and the polished polysilicon substrate after being polished by the above-described CMP step, each polished substrate was removed from the polishing platen. Subsequently, in the same polishing apparatus, each of the polished substrates was attached onto another polishing platen, and then the rinse polishing treatment was applied to the surface of each of the substrates using each of the surface treatment compositions prepared above under the following conditions.

### (Polishing Apparatus and Polishing Conditions)

Polishing apparatus: FREX 300E manufactured by Ebara Corporation
Polishing pad: Soft pad H800 manufactured by Fujibo Co., Ltd.
Polishing pressure: 1.0 psi (1 psi=6894.76 Pa, which similarly applies in the following description)
Number of rotations of polishing platen: 60 rpm
Number of rotations of head: 60 rpm
Supply of polishing composition: One-way
Polishing composition supply amount: 300 mL/min
Polishing time: 60 seconds

### (Water Cleaning Step)

Each of the substrates after the rinse polishing treatment obtained above was cleaned for 60 seconds in a cleaning unit using a PVA brush while being poured with deionized water (DIW). Then, each of the substrates was dried with a spin dryer for 30 seconds.

### Evaluation

Each of the substrates after the water cleaning step obtained above was measured and evaluated for the following items. The evaluation results are shown in Table 1.

### [Measurement of Number of Defects]

The silicon nitride substrate (over 38 nm) and the polysilicon substrate (over 55 nm) after the surface treatment after the water cleaning step obtained above were measured for the number of defects. For the measurement of the number of defects, a wafer defect tester SP-5 manufactured by KLA TENCOR Corporation was used. The measurement was performed for a remaining part excluding a 3 mm wide part from the outer peripheral edge of the surface of each of the substrates after the surface treatment (part ranging from 0 mm to 3 mm in width when the outer peripheral edge is 0 mm).

The evaluation results for each of the surface treatment compositions when the polished silicon nitride substrate was used as the object to be surface treated and when the polished polysilicon substrate was used as the object to be surface treated are as shown in Table 1.

TABLE 1

| | | | | | | | | | | Number of | |
|---|---|---|---|---|---|---|---|---|---|---|---|
| | Vinyl polymer | | | Surfactant | | | | | Physical | defects | |
| | | | Concen- | | | Concen- | pH adjuster | | properties | [pieces/wafer] | |
| | Com- | Molecular | tration | | Molecular | tration | Com- | Com- | pH | SiN | Poly-Si |
| | pound | weight | [g/L] | Compound | weight | [g/L] | ponent | ponent | [—] | >38 nm | >55 nm |
| Ex. 1 | PNVA | 50000 | 1.25 | Ammonium | 288 | 1.00 | Ammonia | Ammonium | 8.7 | 197 | 315 |
| (A-1) | | | | dodecyl | | | | acetate | | | |
| | | | | sulphate | | | | | | | |
| Ex. 2 | PNVA | 50000 | 1.25 | Ammonium | 288 | 0.50 | Ammonia | Ammonium | 8.7 | 207 | 315 |
| (A-2) | | | | dodecyl | | | | acetate | | | |
| | | | | sulphate | | | | | | | |
| Ex. 3 | PNVA | 50000 | 1.25 | Ammonium | 288 | 0.20 | Ammonia | Ammonium | 8.7 | 210 | 383 |
| (A-3) | | | | dodecyl | | | | acetate | | | |
| | | | | sulphate | | | | | | | |
| Ex. 4 | PNVA | 50000 | 1.25 | Ammonium | 288 | 0.10 | Ammonia | Ammonium | 8.7 | 198 | 364 |
| (A-4) | | | | dodecyl | | | | acetate | | | |
| | | | | sulphate | | | | | | | |
| Ex. 5 | PNVA | 50000 | 1.25 | Ammonium | 288 | 1.00 | Ammonia | Ammonium | 7.5 | 185 | 294 |
| (A-5) | | | | dodecyl | | | | acetate | | | |
| | | | | sulphate | | | | | | | |
| Ex. 6 | PNVA | 50000 | 1.25 | Ammonium | 288 | 1.00 | Ammonia | Ammonium | 9.3 | 203 | 301 |
| (A-6) | | | | dodecyl | | | | acetate | | | |
| | | | | sulphate | | | | | | | |
| Ex. 7 | PNVA | 50000 | 1.25 | Ammonium | 288 | 1.00 | Ammonia | Ammonium | 10.0 | 225 | 316 |
| (A-7) | | | | dodecyl | | | | acetate | | | |
| | | | | sulphate | | | | | | | |
| Ex. 8 | PNVA | 50000 | 1.25 | Ammonium | 288 | 1.00 | Ammonia | Ammonium | 11.0 | 191 | 311 |
| (A-8) | | | | dodecyl | | | | acetate | | | |
| | | | | sulphate | | | | | | | |
| Ex. 9 | PNVA | 50000 | 1.25 | Ammonium | 288 | 1.00 | Ammonia | Ammonium | 12.0 | 201 | 283 |
| (A-9) | | | | dodecyl | | | | acetate | | | |
| | | | | sulphate | | | | | | | |
| Ex. 10 | PNVA | 50000 | 1.25 | Polyglycerol | 2000 | 1.00 | Ammonia | Ammonium | 9.3 | 397 | 394 |
| (A-10) | | | | lauryl | | | | acetate | | | |
| | | | | ether | | | | | | | |
| Comp. | PVA | 10000 | 1.00 | — | — | — | Ammonia | Ammonium | 9.3 | 1325 | 614 |
| Ex. 1 | | | | | | | | acetate | | | |
| (a-1) | | | | | | | | | | | |
| Comp. | PNVA | 50000 | 1.25 | PSS-PA | 10000 | 0.10 | — | — | 2.5 | 135 | 649 |
| Ex. 2 | | | | | | | | | | | |
| (a-2) | | | | | | | | | | | |
| Comp. | — | — | — | Ammonium | 288 | 1.00 | | Ammonium | 9.3 | 443 | 1074 |
| Ex. 3 | | | | dodecyl | | | | acetate | | | |
| (a-3) | | | | sulphate | | | | | | | |
| Comp. | — | — | — | Polyglycerol | 2000 | 1.00 | Ammonia | Ammonium | 9.3 | 668 | 1198 |
| Ex. 4 | | | | lauryl | | | | acetate | | | |
| (a-4) | | | | ether | | | | | | | |
| Comp. | PNVA | 50000 | 1.25 | PSS-PA | 10000 | 0.10 | Ammonia | Ammonium | 9.3 | 1016 | 380 |
| Ex. 5 | | | | | | | | acetate | | | |
| (a-5) | | | | | | | | | | | |
| Comp. | PNVA | 50000 | 1.25 | — | — | — | Ammonia | Ammonium | 9.3 | 1189 | 392 |
| Ex. 6 | | | | | | | | acetate | | | |
| (a-6) | | | | | | | | | | | |

As is clear from Table 1 above, it was found that the surface treatment compositions of Examples, which are alkaline, can reduce the number of defects on the surface of the object to be polished after polishing as compared with the surface treatment compositions in Comparative Examples, which are alkaline.

Specifically, the surface treatment compositions in Examples 1 to 9 containing poly-N-vinylacetamide and ammonium dodecyl sulphate and having a pH of 7.5 or more and 12 or less can reduce the number of defects on the surface of particularly the polished silicon nitride substrate as compared with those in Comparative Examples 5, 6 containing poly-N-vinylacetamide, free of ammonium dodecyl sulphate, and having a pH of 9.3. Further, it was found that the surface treatment composition in Example 10 containing poly-N-vinylacetamide and polyglycerol lauryl ether and having a pH of 9.3 can reduce the number of defects on the surface of the polished silicon nitride substrate as compared with those in Comparative Examples 5, 6 containing poly-N-vinylacetamide, free of polyglycerol lauryl ether, and having a pH of 9.3.

From this result, it was found that ammonium dodecyl sulphate or polyglycerol lauryl ether in the alkaline surface treatment compositions has a great effect of reducing the number of defects on the surface of the polished silicon nitride substrate. As the mechanism for reducing the number of defects, it is considered that ammonium dodecyl sulphate or polyglycerol lauryl ether disperses and removes particles and organic residues attached to the surface of the polished silicon nitride substrate.

Further, it was found that the surface treatment compositions in Examples 1 to 10 above can reduce the number of defects on the surface of the polished silicon nitride substrate and the number of defects on the surface of the polished polysilicon substrate as compared with those in Comparative Examples 3, 4 free of poly-N-vinylacetamide, containing ammonium dodecyl sulphate or polyglycerol lauryl ether, and having a pH of 9.3. In particular, Examples 1 to 10 have a greater effect of reducing the number of defects on the surface of the polished polysilicon substrate than that in Comparative Examples 3, 4. From this result, it was found that poly-N-vinylacetamide in the alkaline surface treatment compositions has the effect of reducing the number of defects on the surface of the polished silicon nitride substrate and the number of defects on the surface of the polished polysilicon substrate, and in particular, has a great effect of reducing the number of defects on the surface of the polished polysilicon substrate. As the mechanism for reducing the number of defects, it is considered that poly-N-vinylacetamide hydrophilizes the surface of the polished polysilicon substrate and removes organic residues.

From the above, it was found that the combination use of poly-N-vinylacetamide with ammonium dodecyl sulphate or polyglycerol lauryl ether in the alkaline surface treatment compositions enables sufficient removal of the defects (for example, organic residues) on the surface of the polished silicon nitride substrate and the surface of the polished polysilicon substrate.

1.-20. (canceled)

21. A surface treatment method comprising:
surface treating an object to be polished after polishing using a surface treatment composition to reduce an organic residue on a surface of the object to be polished after polishing,
wherein the object to be polished after polishing contains polysilicon or silicon nitride, and
wherein the surface treatment composition comprising:
a polymer having a constituent unit represented by Formula (1) in [Chem. 1] below;
at least one of an anionic surfactant and a nonionic surfactant; and
water, 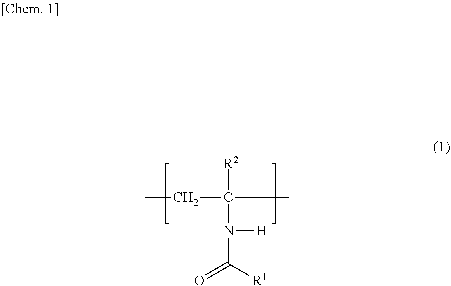
wherein, in Formula (1) above, R¹ is a hydrocarbon group having a number of carbon atoms of 1 to 5, and R² is a hydrogen atom or a hydrocarbon group having the number of carbon atoms of 1 to 3.

22. The surface treatment method according to claim 21, wherein the surface treatment includes rinse polishing or cleaning.
